(19) United States
(12) Patent Application Publication
(10) Pub. No.: US 2023/0234458 A1
(43) Pub. Date: Jul. 27, 2023

(54) CHARGE ADAPTORS FOR SUPPORTING BIDIRECTIONAL ENERGY TRANSFERS BETWEEN MULTIPLE ENERGY UNITS

(71) Applicant: FORD GLOBAL TECHNOLOGIES, LLC, Dearborn, MI (US)

(72) Inventors: Stuart C. Salter, White Lake, MI (US); Ryan O'Gorman, Beverly Hills, MI (US); Timothy Harris, Grosse Ile, MI (US); Peter Phung, Windsor (CA); Katherine Howard-Cone, Canton, MI (US)

(21) Appl. No.: 17/584,665

(22) Filed: Jan. 26, 2022

(51) Int. Cl. B60L 53/16; B60L 55/00; B60L 53/18; B60L 53/66

(52) U.S. Cl. CPC B60L 53/16; B60L 55/00; B60L 53/18; B60L 53/66

(57) ABSTRACT

Charge adaptors may be provided as part of a bidirectional energy transfer system for charging multiple vehicles from a single power source. An exemplary charge adaptor may enable intelligent charging of multiple vehicles from the power source through various configurations (e.g., daisy-chain, multiplex, etc.) and strategies (e.g. sequential, parallel, staged, etc.). A microcontroller of the charge adaptor may serve as the primary controller of energy flow through a bidirectional energy transfer system, with other connected devices such as the charge source, vehicles, and other charge adaptors configured to function as periphery control devices. The charge adaptor may implement an AC coupled design in which a common voltage bus is utilized to splice energy to other charge adaptors for enabling bidirectional energy transfers.

### TECHNICAL FIELD

This disclosure relates generally to charge adaptors configured for concurrently charging multiple vehicles from a single charge source.

### BACKGROUND

Electrified vehicles differ from conventional motor vehicles because they are selectively driven by one or more traction battery pack powered electric machines. The electric machines can propel the electrified vehicles instead of, or in combination with, an internal combustion engine. Plug-in type electrified vehicles include one or more charging interfaces for charging the traction battery pack. Plug-in type electrified vehicles are commonly charged while parked at a charging station or some other utility power source. Typically, charging stations are only capable of charging one vehicle at a time.

### SUMMARY

A charge adaptor for a bidirectional energy transfer system according to an exemplary aspect of the present disclosure includes, among other things, an inlet port configured to connect to a first charging cable, a coupler configured to operably connect to a vehicle charge port assembly, an outlet port configured to connect to a second charging cable, and a microcontroller programmed to execute arbitration logic for controlling a flow of energy within the bidirectional energy transfer system.

In a further non-limiting embodiment of the foregoing charge adaptor, the inlet port, the coupler, and the outlet port operate on a common voltage bus.

In a further non-limiting embodiment of either of the foregoing charge adaptors, a first set of relays is adapted to control the flow of the energy transferred to/from the outlet port, and a second set of relays is adapted to control the flow of the energy transferred to/from the coupler.

In a further non-limiting embodiment of any of the foregoing charge adaptors, the charge adaptor is connected between a charge source and a vehicle of the bidirectional energy transfer system.

In a further non-limiting embodiment of any of the foregoing charge adaptors, the charge adaptor further includes a first power line, a second power line, a ground line, a control pilot line, and a proximity pilot line.

In a further non-limiting embodiment of any of the foregoing charge adaptors, the first charging cable, the second charging cable, and the coupler each include wires/pins that correspond to each of the first power line, the second power line, the ground line, the control pilot line, and the proximity pilot line for transferring the energy and communicating signals within the charge adaptor.

In a further non-limiting embodiment of any of the foregoing charge adaptors, a power supply is configured for selectively powering the microcontroller.

In a further non-limiting embodiment of any of the foregoing charge adaptors, the microcontroller is a local interconnect network (LIN) microcontroller.

In a further non-limiting embodiment of any of the foregoing charge adaptors, a wireless communications device is adapted for establishing wireless communications between the charge adaptor and other components of the bidirectional energy transfer system.

In a further non-limiting embodiment of any of the foregoing charge adaptors, a current sensor is configured to measure an amount of current flowing through the outlet port.

A bidirectional energy transfer system according to another exemplary aspect of the present disclosure includes, among other things, a charge source, a first vehicle including a first traction battery pack, a second vehicle including a second traction battery pack, and a charge adaptor configured to establish a common voltage bus for transferring energy received from the charge source to each of the first vehicle and the second vehicle for simultaneously charging the first traction battery pack and the second traction battery pack.

In a further non-limiting embodiment of the foregoing system, the charge adaptor includes a microcontroller programmed to execute arbitration logic for controlling a flow of the energy from the charge source to each of the first vehicle and the second vehicle.

In a further non-limiting embodiment of either of the foregoing systems, the microcontroller is further programmed to estimate a number of splicing connections of the charge adaptor based on feedback from a current sensor of the charge adaptor.

In a further non-limiting embodiment of any of the foregoing systems, the number of splicing connections is estimated based on a resistance delta measurement that is derived from a look-up table.

In a further non-limiting embodiment of any of the foregoing systems, the microcontroller is a local interconnect network (LIN) microcontroller.

In a further non-limiting embodiment of any of the foregoing systems, the microcontroller is further programmed to execute the arbitration logic using a sequential energy transfer strategy, a parallel energy transfer strategy, or a staged energy transfer strategy.

In a further non-limiting embodiment of any of the foregoing systems, the microcontroller is further programmed to prioritize and stagger the flow of the energy to the first vehicle and the second vehicle based on the arbitration logic.

In a further non-limiting embodiment of any of the foregoing systems, the charge adaptor includes a first power line, a second power line, a ground line, a control pilot line, and a proximity pilot line.

In a further non-limiting embodiment of any of the foregoing systems, the charge adaptor is connected to the charge source by a first charging cable, and the charge adaptor includes a coupler that is configured to connect to a charge port assembly of the first vehicle. The charge adaptor is connected to the second vehicle by a second charging cable.

In a further non-limiting embodiment of any of the foregoing systems, a second charge adaptor is connected to a charge port assembly of the second vehicle, and a third charging cable is connected to the second charge adaptor and a third vehicle.

The embodiments, examples, and alternatives of the preceding paragraphs, the claims, or the following description and drawings, including any of their various aspects or respective individual features, may be taken independently or in any combination. Features described in connection with one embodiment are applicable to all embodiments, unless such features are incompatible.

The various features and advantages of this disclosure will become apparent to those skilled in the art from the following detailed description. The drawings that accompany the detailed description can be briefly described as follows.

### BRIEF DESCRIPTION OF THE DRAWINGS

FIG. 1 schematically illustrates a bidirectional energy transfer system configured for charging multiple vehicles from a single charge source.

FIG. 2 schematically illustrates an exemplary charging adaptor of a bidirectional energy transfer system.

FIG. 3 schematically illustrates an exemplary configuration of a bidirectional energy transfer system.

FIG. 4 schematically illustrates another exemplary configuration of a bidirectional energy transfer system.

FIG. 5 schematically illustrates another exemplary configuration of a bidirectional energy transfer system.

FIG. 6 schematically illustrates yet another exemplary configuration of a bidirectional energy transfer system.

FIGS. 7A and 7B schematically illustrate an exemplary method of controlling a bidirectional energy transfer system for charging multiple vehicles from a single charge source.

### DETAILED DESCRIPTION

This disclosure relates to charge adaptors for charging multiple vehicles from a single power source. An exemplary charge adaptor may enable intelligent charging of multiple vehicles from the power source through various configurations (e.g., daisy-chain, multiplex, etc.) and strategies (e.g. sequential, parallel, staged, etc.). A microcontroller of the charge adaptor may serve as the primary controller of energy flow through a bidirectional energy transfer system, with other connected devices such as the charge source, vehicles, and other charge adaptors configured to function as periphery control devices. The charge adaptor may implement an AC coupled design in which a common voltage bus is utilized to splice energy to other charge adaptors for enabling bidirectional energy transfers. These and other features of this disclosure are discussed in greater detail in the following paragraphs of this detailed description.

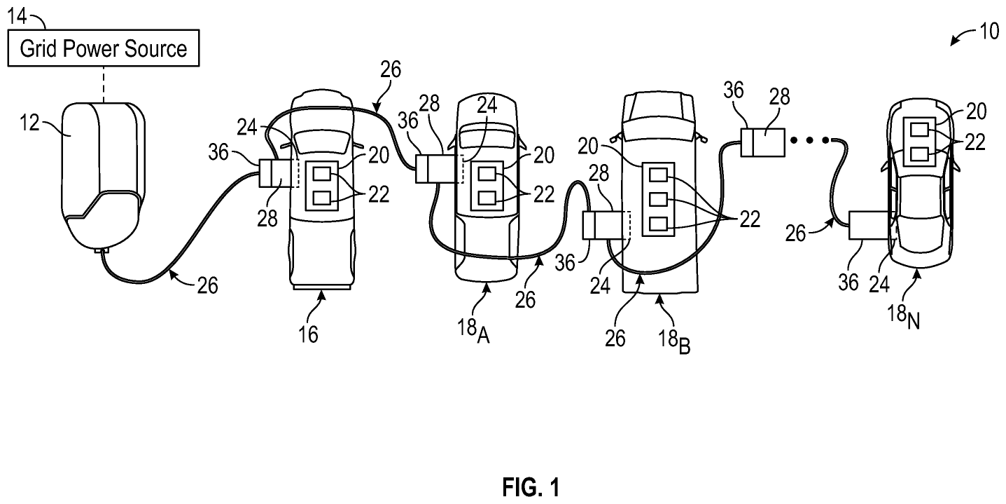

FIG. 1 schematically illustrates an exemplary bidirectional energy transfer system 10 (hereinafter “the system 10”) for bidirectionally transferring energy between multiple vehicles. In particular, the system 10 may be utilized to simultaneously charge multiple vehicles from a single charge source 12. The charge source 12 may be a public charging station, a home charging station (e.g., a wall box), a DC fast charging station, or any other type of charge source.

The charge source 12 may be operably coupled to a grid power source 14 (e.g., AC power, solar power, wind power, or combinations thereof). The charge source 12 may therefore provide the interface for charging the one or more vehicles using power supplied by the grid power source 14.

A host vehicle 16 may be operably connected to the charge source 12, and one or more surrogate vehicles 18_{A} to 18_{N}, where “N” represents any number, may be operably connected to the host vehicle 16. The system 10 may be configured to enable bidirectional transfers of energy from the charge source 12, to the host vehicle 16, and then to the one or more surrogate vehicles 18, or from the host vehicle 16 and/or one or more of the surrogated vehicles 18 back to the charge source 12, such as for powering household loads, for example. Unless stated otherwise herein, the reference numeral “18” may refer to any of the surrogate vehicles when used without any alphabetic identifier immediately following the reference numeral.

In an embodiment, the host vehicle 16 and each connected surrogate vehicle 18 are plug-in type electrified vehicles (e.g., plug-in hybrid electric vehicles (PHEVs) or battery electric vehicles (BEV)). The host vehicle 16 and the surrogate vehicles 18 may each include a traction battery pack 20 (or any other type of energy storage unit) that is part of an electrified powertrain capable of applying torque from an electric machine (e.g., an electric motor) for driving the respective drive wheels of each vehicle. Therefore, the powertrain of each vehicle associated with the system 10 may electrically propel the respective set of drive wheels either with or without the assistance of an internal combustion engine.

Although shown schematically, each traction battery pack 20 linked to the system 10 may be configured as a high voltage traction battery pack that includes a plurality of battery arrays 22 (e.g., battery assemblies or groupings of battery cells) capable of outputting electrical power to one or more electric machines. Other types of energy storage units and/or output devices may also be used to electrically power the vehicles 16, 18 associated with the system 10.

In the illustrated embodiment, the host vehicle 16 and the surrogate vehicle 18_{A} are schematically illustrated as pickup trucks, the surrogate vehicle 18_{B} is schematically illustrated as a van, and the surrogate vehicle 18_{N} is schematically illustrated as a sedan. However, other vehicle configurations are also contemplated within the scope of this disclosure. The teachings of this disclosure should therefore be understood to be applicable for any type of vehicle as the host vehicle 16 and for any type of vehicle as each of the surrogate vehicles 18. For example, the vehicles associated with the system 10 could include any combination of cars, trucks, vans, sport utility vehicles (SUVs), etc.

Although a specific component relationship is illustrated in the figures of this disclosure, the illustrations are not intended to limit this disclosure. The placement and orientation of the various components of the depicted vehicles are shown schematically and could vary within the scope of this disclosure. In addition, the various figures accompanying this disclosure are not necessarily drawn to scale, and some features may be exaggerated or minimized to emphasize certain details of a particular component.

From time to time, charging the energy storage devices (e.g., battery cells) of the traction battery pack 20 of each vehicle 16, 18 may be required or desirable. Each vehicle 16, 18 may therefore be equipped with a charging system that includes one or more charge port assemblies 24. The exact positioning of each charge port assembly 24 shown in FIG. 1 is exemplary only and is not intended to limit this disclosure. Each charge port assembly 24 could be located at any accessible location (e.g., front exterior, rear exterior, truck bed or other cargo space locations, etc.) of each vehicle 16, 18.

A plurality of charging cables 26 may be used to operably connect the vehicles 16, 18 of the system 10 to the charge source 12. The system 10 may further include one or more charge adaptors 28 that enable multiple vehicles 16, 18 to be charged (or exchange energy in a desired manner) from the charge source 12 concurrently. In the illustrated embodiment, one charge adaptor 28 is connected to each charge port assembly 24, and a first charging cable 26 may be operably connected between the charge source 12 and a first charge adaptor 28 that is coupled to the charge port assembly 24 of the host vehicle 16, a second charging cable 26 may be operably connected between the first charge adaptor 28 and a second charge adaptor 28 that is coupled to the charge port assembly 24 of the surrogate vehicle 18_{A}, a third charging cable 26 may be operably connected between the second charge adaptor 28 and a third charge adaptor 28 that is coupled to the charge port assembly 24 of the surrogate vehicle 18_{B}, and so on for operably connecting the “N” number of surrogate vehicles 18 to the system 10 for charging/transferring energy. The total number of charging cables 26 and charge adaptors 28 employed within the system 10 is not intended to limit this disclosure and can vary depending upon the number of surrogate vehicles 18 that are present during a bidirectional energy transfer event, for example.

Although not specifically shown in the highly schematic depiction of FIG. 1, the respective charging system of each vehicle 16, 18 may be equipped with various components for enabling bidirectional transfers of power to/from the energy storage unit of each respective vehicle. Exemplary components for enabling bidirectional transfers of power may include but are not limited to a charger, a DC-DC converter, high voltage relays or contactors, a motor controller (which may be referred to as an inverter system controller or ISC), etc.

The system 10 may be configured to employ passthrough charging techniques when charging the multiple vehicles 16, 18 from the charge source 12. In this disclosure, the term “passthrough charging” indicates the ability of a vehicle to transfer all or a portion of the power received from a charge source to another vehicle for addressing that vehicle's charging needs without the other vehicle being directly connected to the charge source 12.

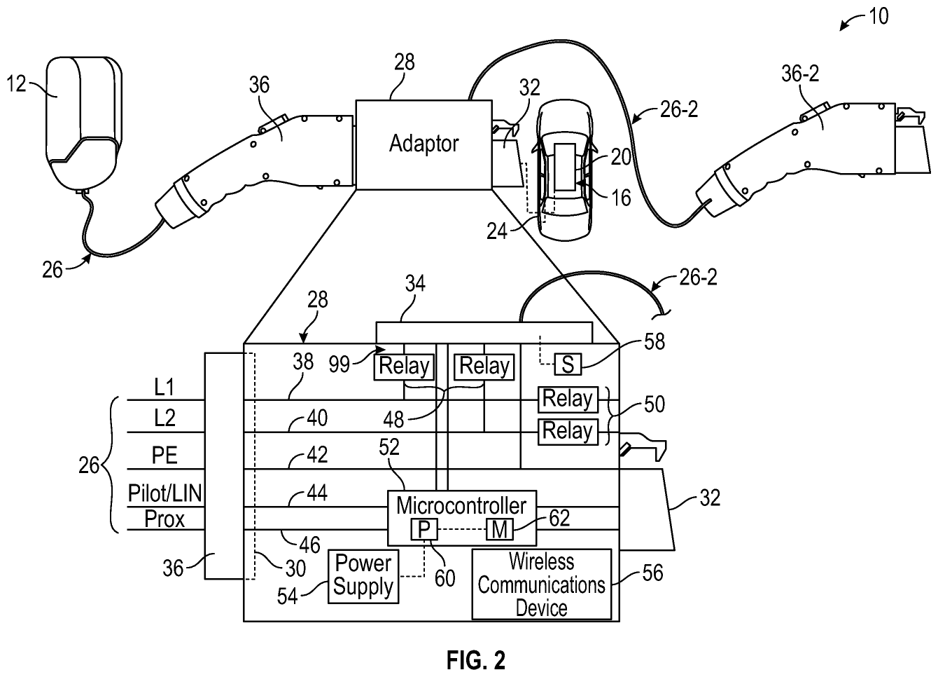

An exemplary charge adaptor 28 of the system 10 is illustrated in FIG. 2. In the illustrated embodiment, the charge adaptor 28 is connected between the charge source 12 and a host vehicle 16. Additional charge adaptors of the system 10 could employ a configuration that is similar to the charge adaptor 28 shown in FIG. 2.

The charge adaptor 28 may include an inlet port 30, a coupler 32, and an outlet port 34. The inlet port 30 may be configured to receive a coupler 36 of a charging cable 26 that is operably connected to the charge source 12. In an embodiment, the inlet port 30 and the coupler 36 each include an SAE J1772 type charging interface. However, other charging interfaces could alternatively be employed.

The coupler 32 of the charge adaptor 28 may be plugged into a charge port assembly 24 of the host vehicle 16. In an embodiment, the charge port assembly 24 and the coupler 32 each include an SAE J1772 type charging interface. However, other charging interfaces could alternatively be employed.

The outlet port 34 may be configured to operably connect an additional charging cable 26-2 to the system 10. The additional charge cable 26-2 may then be operably connected to either another charge adaptor or to a charge port assembly of a surrogate vehicle via a coupler 36-2.

Although the inlet port 30 and the outlet port 34 are shown as including single port configurations, multi-port configurations are also within the scope of this disclosure. Therefore, multiple charge cables 26 could be connected at both the inlet and outlet portions of the charge adaptor 28.

The charge adaptor 28 may include a first power line 38, a second power line 40, a ground line 42, a control pilot line 44, and a proximity pilot line 46. The charging cables 26, 26-2, the charge port assembly 24, and the coupler 32 may include wires/pins that correspond to each of the lines 38-46 for bidirectionally transferring power and communicating signals between the connected components of the system 10.

The first power line 38 may be a positive AC power line, and the second power line 40 may be either a neutral AC power line (e.g., for Level 1 charging) or a negative AC power line (e.g., for Level 2 charging). Power may be transferred to/from each of inlet port 30, the coupler 32, and the outlet port 34 via the first and second power lines 38, 40. In an embodiment, the charge adaptor 28 operates via an AC coupled design in which a common voltage bus 99 is utilized to splice energy from the charge adaptor 28 to additional charge adaptors and/or connected vehicle units of the system 10 during bidirectional energy transfer events.

A first set of relays 48 may control the amount of power that is transferred to/from the outlet port 34 within the first and second power lines 38, 40. A second set of relays 50 may control the amount of power that is transferred to/from the coupler 32 within the first and second power lines 38, 40.

The control pilot line 44 may be configured for communicating various signals between connected components of the system 10 during bidirectional energy transfer events. For example, signals such as charging status signals, charging level signals, charging control signals, charging error signals, etc. may be communicated over the control pilot line 44 during bidirectional energy transfer events.

The proximity pilot line 46 may be configured for communicating various status signals during bidirectional energy transfer events. For example, status signals such as plug connection signals may be communicated over the proximity pilot line 46 when the charging cable 26 is connected to the inlet port 30 and/or when the coupler 32 is connected to the charge port assembly 24 of the host vehicle 16.

The charge adaptor 28 may further include a microcontroller 52 and a power supply 54. The power supply 54 may selectively power the microcontroller 52, such as when power is unavailable from the charge source 12 or any other connected energy unit of the system 10, for example.

In an embodiment, the microcontroller 52 is a local interconnect network (LIN) microcontroller. The microcontroller 52 may therefore communicate LIN messages over the control pilot line 44 for communicating with the various components of the system 10. As a security measure, LIN messages communicated over the control pilot line 44 of the charge adaptor 28 may be encrypted. The microcontroller 52 may therefore be programmed to request and receive notification of mutual authentication of all relevant parties that are associated with the system 10 prior to initiating bidirectional energy transfers.

The charge adaptor 28 may alternatively or additionally include a wireless communications device 56 for wirelessly communicating with other connected components of the system 10. For example, the wireless communications device 56 may enable the charge adaptor 28 to wirelessly communicate with respective wireless communications devices of the charge source 12, the host vehicle 16, the surrogate vehicle(s) 18, additional charge adaptors, charging cables, etc. The wireless communications device 56 may transmit signals throughout the system 10 using any known wireless communication protocol (e.g., cellular, Wi-Fi, Bluetooth®, data connectivity, etc.).

The charge adaptor 28 may further include a current sensor 58. The current sensor 58 may be imbedded within or otherwise mounted near the outlet port 34 of the charge adaptor 28 and may be configured to measure an amount of current flowing to/from the outlet port 34. As is further discussed below, current measurements obtained by the current sensor 58 may be communicated to the microcontroller 52 for identifying the number of circuit connections of the system 10.

The microcontroller 52 may include a processing unit 60 and non-transitory memory 62 for executing various control strategies of the system 10. The processing unit 60 can be programmed to execute one or more programs stored in the memory 62. The programs may be stored in the memory 62 as software code, for example. The programs stored in the memory 62 may each include one or more ordered lists of executable instructions for implementing logical functions associated with the system 10.

The processing unit 60 can be a custom made or commercially available processor, a central processing unit (CPU), or generally any device for executing software instructions. The memory 62 can include any one or combination of volatile memory elements and/or nonvolatile memory elements.

In an embodiment, the microcontroller 52 may be programmed to infer the number of connections that are present in a charging circuit of the system 10 based on the current measurements received from the current sensor 58. This may be accomplished through resistance delta measurements that may be derived from one or more look-up tables that can be stored within the memory 62 of the microcontroller 52. Increases in resistances, which may be derived via the look-up table, may thus be utilized to provide an estimation of the number of vehicles 16, 18 that are connected to the system 10.

In another embodiment, based at least on the number of vehicles 16, 18 that are identified as being connected to the system 10, the microcontroller 52 may be programmed to execute arbitration logic for controlling the flow of energy to/from each of the various energy units associated with the system 10. For example, input power from the charge source 12 may be broadcast to the microcontroller 52 of the charge adaptor 28, and in turn, the microcontroller 52 may arbitrate the energy transfer to each respective vehicle 16, 18 of the system 10 through programmed strategies that would best serve the current charging-related conditions of a user/fleet (e.g. sequential/waterfall, parallel, staged transfers, etc.)

During a sequential/waterfall energy transfer strategy, for example, the host vehicle 16 may be charged to a specific target before charging subsequent surrogate vehicles 18 of the system 10. For example, the traction battery pack 20 of the host vehicle 16 may first be charged from the charge source 12 to a first target (e.g., 90% state of charge) before beginning to charge the surrogate vehicle 18_{A}. The surrogate vehicle 18_{A} may then be charged to a second target (e.g., 95% state of charge) before beginning to charge the next surrogate vehicle 18_{B}. The surrogate vehicle 18_{B} may then be charged to a third target (e.g., 80% state of charge) before beginning to charge the next surrogate vehicle 18_{N}, and so on.

During a parallel energy transfer strategy, for example, charge energy from the charge source 12 may be transferred across multiple vehicles 16, 18 simultaneously. For example, the traction battery pack 20 of the host vehicle 16 may be charged to a first target, the traction battery pack 20 of the surrogate vehicle 18_{A} may be charged to a second target, the traction battery pack 20 of the surrogate vehicle 18_{B} may be charged to a third target, and so on, simultaneously.

During a staged energy transfer strategy, for example, a combination of sequential and parallel strategies may be utilized for transferring charge energy throughout the system 10. For example, the microcontroller 52 may command that charge energy be transferred for charging the traction battery pack 20 of the surrogate vehicle 18_{A} first. Once the surrogate vehicle 18_{A} has been charged to its desired target, the microcontroller 52 may then command that the host vehicle 16 and the surrogate vehicle 18_{B} (and any other surrogate vehicles) be charged to their respective targets simultaneously.

In another embodiment, the microcontroller 52 may be programmed to prioritize and stagger energy transfers between the connected energy units of the system 10. This may include commanding that charge energy flow in multiple directions, such as through phase synchronization techniques, during bidirectional energy transfer events. As part of such a prioritized and staggered process, the microcontroller 52 may be programmed to command a momentary pause for transfer sequencing. The pause would maintain the connected vehicles of the system 10 in a paused state until a precharge sequence has been completed. During the pause (e.g., about 100 milliseconds), the microcontroller 52 may assess and prioritize the energy transfer to each connected unit of the system 10 with a staggered approach (e.g., surrogate vehicle 18_{A} to receive charge energy first, then surrogate vehicle 18_{B} can receive concurrent energy transfer a few seconds later, etc.).

Logic for controlling the transfer of charge energy during bidirectional energy transfer events may be arbitrated by the microcontroller 52 using a variety of approaches. A first exemplary approach may be referred to as a preset approach. During the preset approach, a pilot detection signal from the charge adaptor 28 may be utilized to allow for a targeted amount (e.g., 40 amps) of charge energy to be transferred to each connected unit of the system 10. The targeted amount may be either calibratable or programmed by a user.

Another exemplary approach may be referred to as an imbedded intelligence/logic approach. During this approach, the microcontroller 52 may rely on real-time sensor feedback, such as that received from the current sensor 58, to automatically adjust the charge energy transferred to each unit of the system 10 during bidirectional energy transfer events.

Additional approaches could base bidirectional energy transfers of the system 10 on factors such as time of day, user calendar information, amount of time available for transfer, amount of desired range after charge, etc.

In another embodiment, the microcontroller 52 may be programmed to communicate with the charge source 12 and any additional charge adaptor 28 of the system during bidirectional energy transfer events. Charging status details and other information from each connected unit of the system 10 may therefore be exchanged for monitoring by the microcontroller 52. In some implementations, the charging status and other information related to the bidirectional energy transfer event may be uploaded to a cloud based served and accessed through a web-based application (e.g., FordPass™) for allowing users to interface with the system 10.

In the configuration shown in FIG. 1, the charging cables 26 and charge adaptors 28 are arranged in a daisy-chain configuration. However, other configurations are made possible by the exemplary charge adaptors 28 of this disclosure.

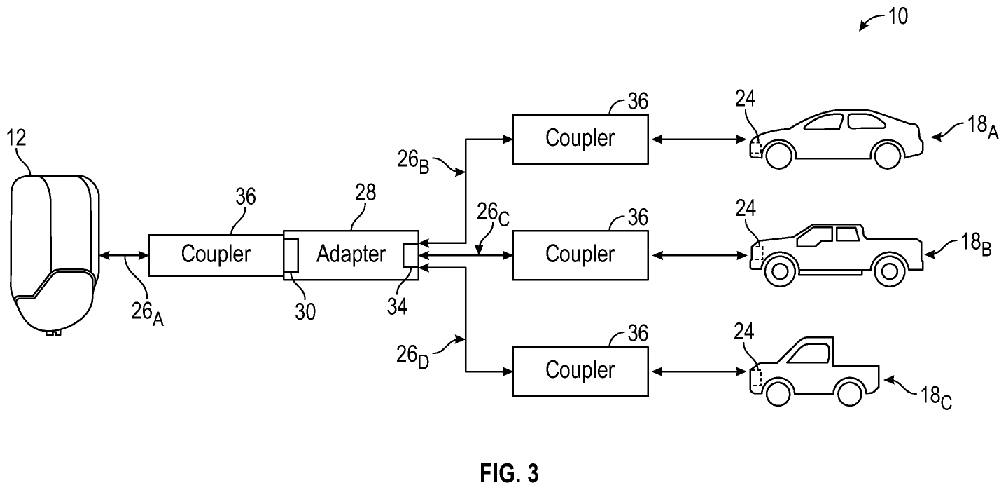

Referring to FIG. 3, for example, an exemplary multiplex configuration of the system 10 is illustrated for simultaneously charging multiple vehicles 18_{A}, 18_{B}, and 18_{C} from a single charge source 12. A first charging cable 26_{A} is connected to the charge source 12. A coupler 36 of the first charging cable 26_{A} is connected to an inlet port 30 of the charge adaptor 28. Additional charge cables 26_{B}, 26_{C}, and 26_{D} are coupled to an outlet port 34 of the charge adaptor 28. The charge cable 26_{B} is coupled to a charge port assembly 24 of the vehicle 18_{A}, the charge cable 26_{C} is coupled to a charge port assembly 24 of the vehicle 18_{B}, and the charge cable 26_{C} is coupled to a charge port assembly 24 of the vehicle 18_{C} (e.g., via couplers 36). The vehicles 18_{A}, 18_{B}, and 18_{C} may therefore receive charge energy from the charge source 12 in parallel with one another.

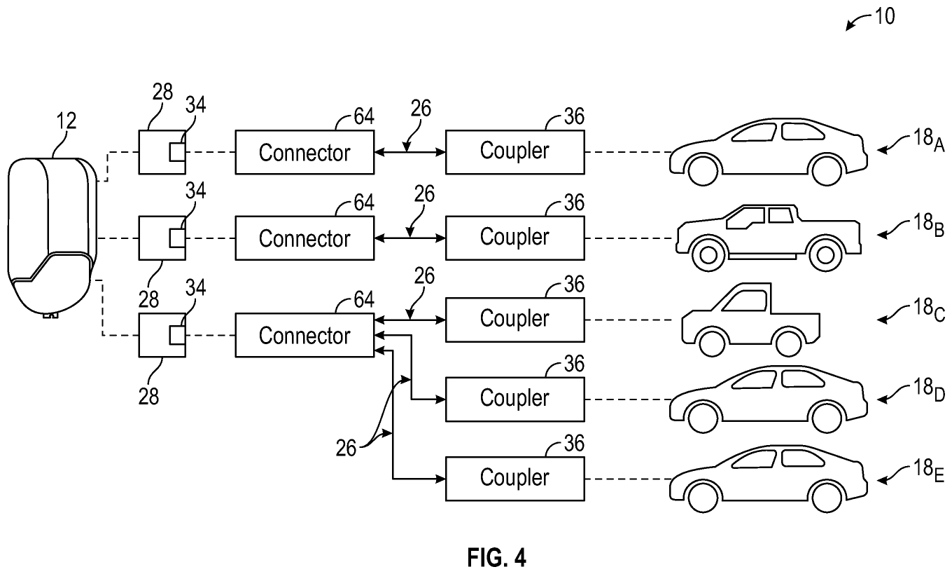

FIG. 4 illustrates another exemplary multiplex configuration of the system 10 for simultaneously charging multiple vehicles 18_{A}, 18_{B}, 18_{C}, 18_{D}, and 18_{E} from a single charge source 12. In this configuration, multiple charge adaptors 28 are connected directly to the charge source 12. A connector 64 may be operably connected to each charge adaptor 28. Each connector 64 may provide a different charging interface than that provided by the charge adaptor 28 it is connected to. One or more charging cables 26 may be operably coupled to each connector 64 and then connected to one of the vehicles 18_{A}, 18_{B}, 18_{C}, 18_{D}, and 18_{E} (e.g., by couplers) for charging the vehicles 18 in parallel. By using the connectors 64, the charge adaptors 28 of this disclosure may be utilized to charge multiple vehicles simultaneously even when one or more of the vehicles are equipped with a different charging interface than the other vehicles of the system 10.

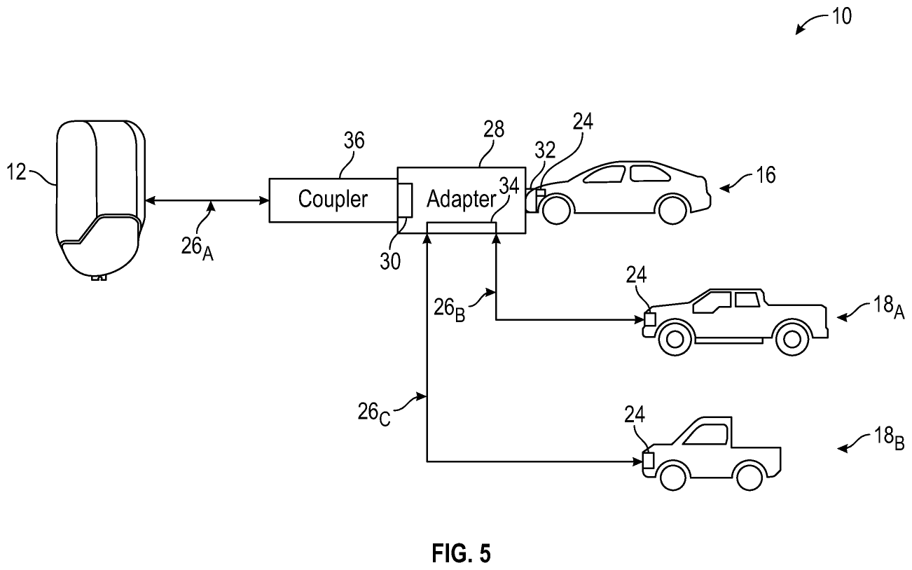

FIG. 5 illustrates another exemplary multiplex configuration of the system 10 for simultaneously charging a host vehicle 16 multiple surrogate vehicles 18_{A} and 18_{B} A first charging cable 26_{A} is connected to the charge source 12. A coupler 36 of the first charging cable 26_{A} is connected to an inlet port 30 of the charge adaptor 28. A coupler 32 of the charge adaptor 28 is connected to a charge port assembly 24 of the host vehicle 16. Additional charge cables 26_{B} and 26_{C} are coupled to an outlet port 34 of the charge adaptor 28. The charge cable 26_{B} is coupled to a charge port assembly 24 of the vehicle 18_{A}, and the charge cable 26_{c} is coupled to a charge port assembly 24 of the vehicle 18_{B}. The vehicles 16, 18_{A}, and 18_{B} may therefore receive charge energy from the charge source 12 in parallel with one another.

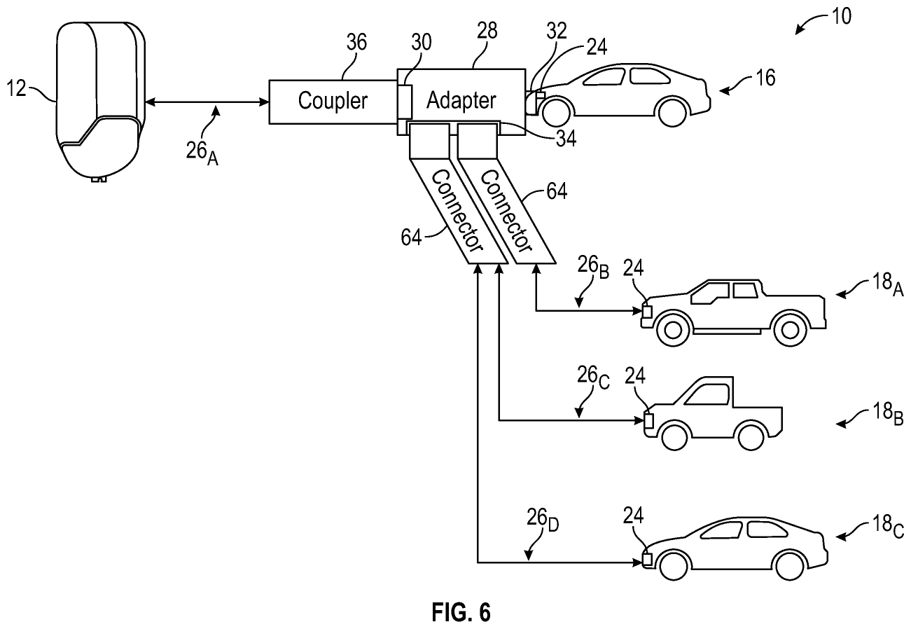

FIG. 6 illustrates another exemplary multiplex configuration of the system 10 for simultaneously charging a host vehicle 16 and multiple surrogate vehicles 18_{A}, 18_{B}, and 18_{C}. A first charging cable 26_{A} is connected to the charge source 12. A coupler 36 of the first charging cable 26_{A} is connected to an inlet port 30 of the charge adaptor 28. A coupler 32 of the charge adaptor 28 is connected to a charge port assembly 24 of the host vehicle 16. Connectors 64 may be coupled to an outlet port 34 of the charge adaptor 28. One or more additional charging cables 26_{B}, 26_{C}, and 26_{D} may be operably coupled to the connectors 64. The charging cable 26_{B} may then be coupled to a charge port assembly 24 of the vehicle 18_{A}, the charging cable 26_{C} may be coupled to a charge port assembly 24 of the vehicle 18_{B}, and charging cable 26_{D} may be coupled to a charge port assembly 24 of the vehicle 18_{C}. The vehicles 16, 18_{A}, 18_{B}, and 18_{C} may therefore receive charge energy from the charge source 12 in parallel with one another and irrespective of whether one or more of the vehicles are equipped with a different charging interface than the other vehicles of the system 10.

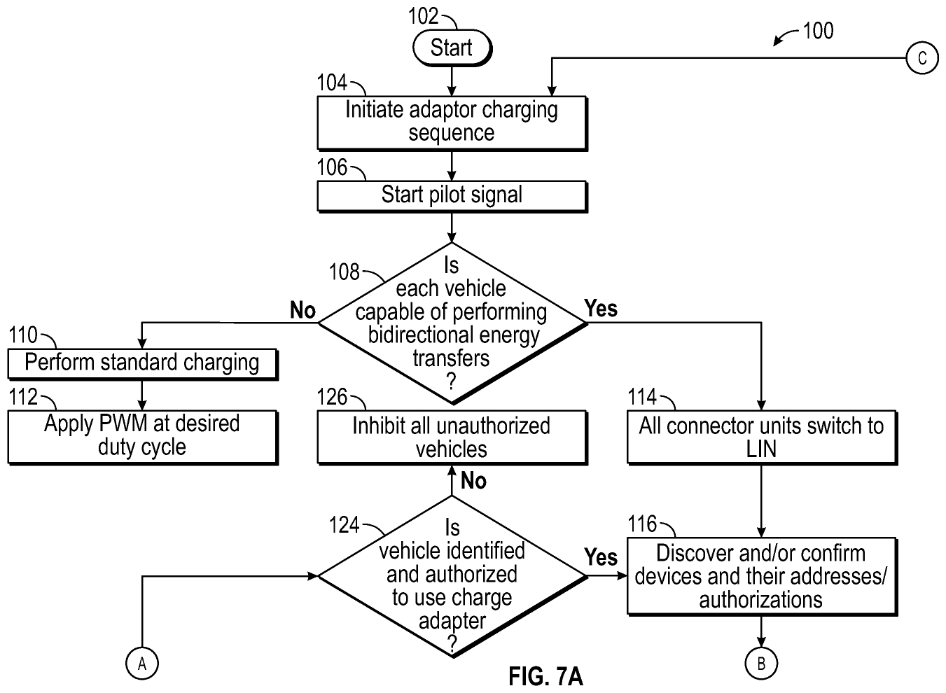

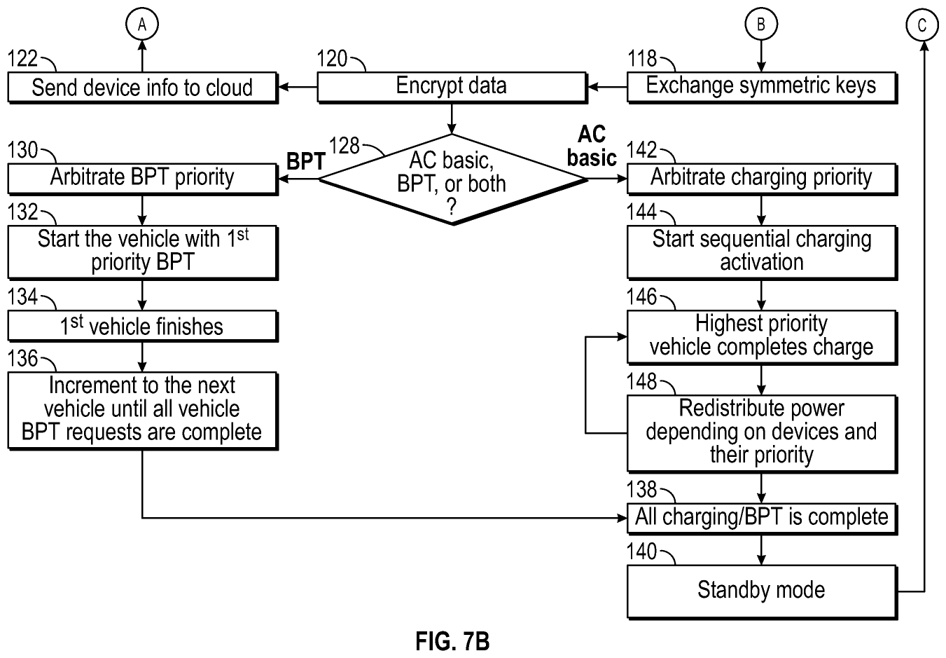

FIGS. 7A and 7B, with continued reference to FIGS. 1-6, schematically illustrate in flow chart form an exemplary method 100 for controlling the system 10 in order to coordinate and provide bidirectional energy transfer events from the charge adaptor 28. The system 10 may be configured to employ one or more algorithms adapted to execute at least a portion of the steps of the exemplary method 100. For example, the method 100 may be stored as executable instructions in the memory 62 of the microcontroller 52, and the executable instructions may be embodied within any computer readable medium that can be executed by the processing unit 60 of the microcontroller 52. The method 100 could alternatively or additionally be stored as executable instructions in the memories of comparable controllers of one or more of the charge source 12, additional charge adaptors, or any of the vehicles 16, 18 associated with the system 10.

The exemplary method 100 may begin at block 102. The method 100 assumes that the participating vehicles of the system 10 are already connected using a plurality of charging cables 26 and that at least one charge adaptor 28 is connected within the system 10, for example.

At block 104, the method 100 may initiate a charge sequence of the charge adaptor 28. A pilot signal 106 may then be started at the charge adaptor 28 at block 106 to confirm the plug connection status. The pilot signal 106 may be communicated over the proximity pilot line 46, for example.

Next, at block 108, the method 100 may determine whether each connected vehicle 16, 18 of the system 10 is capable of performing bidirectional energy transfers. If NO, the method 100 may determine that standard charging should be performed at block 110. Then, at block 112, the method 100 may initiate standard charging, such as by commanding a pulse width modulation (PMW) charging signal at a desired duty cycle (e.g., 96%).

Alternatively, if a YES flag is returned at block 108, the method 100 may proceed to block 114. At this step, all connected units of the system 10 may be commanded to switch to LIN communications. The method 100 may then, at block 116, discover and/or confirm the address/authorizations for each connected unit of the system 10. Symmetric keys may be exchanged at block 118, data encryption may commence at block 120, and data associated with each connected unit may be communicated to a cloud-based server at block 122.

Next, at block 124, the method 100 may determine whether each vehicle 16, 18 of the system 10 has been identified and is authorized to participate within the system 10 for charging events. If NO, energy transfer to any unauthorized vehicle is inhibited at block 126. If YES, the method 100 may return to block 116, and blocks 116 to 120 may be repeated before proceeding to block 128 when all authorizations and confirmations have been confirmed/completed.

At block 128, the method 100 may determine whether to proceed with AC basic charging, bidirectional power transfer, or both. If bidirectional power transfer is selected as being appropriate, the method 100 may proceed to block 130 and begin arbitrating bidirectional transfer priority for each vehicle 16, 18 of the system 10. The method 100 may then command bidirectional energy transfer to the vehicle of first priority at block 132. After confirming that the vehicle of first priority has reached its charging target at block 134, the method 100 may proceed to block 136 by incrementing to each of the vehicles of next charge priority until all connected vehicles of the system 10 have been accounted for.

The method 100 may confirm that the charging of all authorized vehicles is complete at block 138. The system 10 may then enter a standby mode at block 140.

If AC basic charging is selected as being appropriate at block 128, the method 100 may proceed to block 142 and begin arbitrating energy transfer priority for each vehicle 16, 18 of the system 10. Sequential charging activation may then be commenced at block 144. At block 146, the method 100 may confirm that the vehicle of highest charging priority has completed its charge. The method 100 may then redistribute power to the remaining vehicles of the system 10 based on their respective charge priorities.

The method 100 may then confirm that charging of all authorized vehicles is complete at block 138. The system 10 may then enter the standby mode at block 140.

The bidirectional energy transfer systems of this disclosure may utilize one or more charge adaptors for enabling charging of multiple vehicles simultaneously and from a common charge source. The proposed systems may facilitate a more streamlined and convenient usage of charging stations/wall boxes and may further facilitate bidirectional energy transfers without the need for added infrastructure.

Although the different non-limiting embodiments are illustrated as having specific components or steps, the embodiments of this disclosure are not limited to those particular combinations. It is possible to use some of the components or features from any of the non-limiting embodiments in combination with features or components from any of the other non-limiting embodiments.

It should be understood that like reference numerals identify corresponding or similar elements throughout the several drawings. It should be understood that although a particular component arrangement is disclosed and illustrated in these exemplary embodiments, other arrangements could also benefit from the teachings of this disclosure.

The foregoing description shall be interpreted as illustrative and not in any limiting sense. A worker of ordinary skill in the art would understand that certain modifications could come within the scope of this disclosure. For these reasons, the following claims should be studied to determine the true scope and content of this disclosure.

What is claimed is:

1. A charge adaptor for a bidirectional energy transfer system, comprising:
an inlet port configured to connect to a first charging cable;
a coupler configured to operably connect to a vehicle charge port assembly;
an outlet port configured to connect to a second charging cable; and
a microcontroller programmed to execute arbitration logic for controlling a flow of energy within the bidirectional energy transfer system.

2. The charge adaptor as recited in claim 1, wherein the inlet port, the coupler, and the outlet port operate on a common voltage bus.

3. The charge adaptor as recited in claim 1, comprising a first set of relays adapted to control the flow of the energy transferred to/from the outlet port, and a second set of relays adapted to control the flow of the energy transferred to/from the coupler.

4. The charge adaptor as recited in claim 1, wherein the charge adaptor is connected between a charge source and a vehicle of the bidirectional energy transfer system.

5. The charge adaptor as recited in claim 1, wherein the charge adaptor further comprises a first power line, a second power line, a ground line, a control pilot line, and a proximity pilot line.

6. The charge adaptor as recited in claim 5, wherein the first charging cable, the second charging cable, and the coupler each include wires/pins that correspond to each of the first power line, the second power line, the ground line, the control pilot line, and the proximity pilot line for transferring the energy and communicating signals within the charge adaptor.

7. The charge adaptor as recited in claim 1, comprising a power supply configured for selectively powering the microcontroller.

8. The charge adaptor as recited in claim 1, wherein the microcontroller is a local interconnect network (LIN) microcontroller.

9. The charge adaptor as recited in claim 1, comprising a wireless communications device adapted for establishing wireless communications between the charge adaptor and other components of the bidirectional energy transfer system.

10. The charge adaptor as recited in claim 1, comprising a current sensor configured to measure an amount of current flowing through the outlet port.

11. A bidirectional energy transfer system, comprising:
a charge source;
a first vehicle including a first traction battery pack;
a second vehicle including a second traction battery pack; and
a charge adaptor configured to establish a common voltage bus for transferring energy received from the charge source to each of the first vehicle and the second vehicle for simultaneously charging the first traction battery pack and the second traction battery pack.

12. The system as recited in claim 11, wherein the charge adaptor includes a microcontroller programmed to execute arbitration logic for controlling a flow of the energy from the charge source to each of the first vehicle and the second vehicle.

13. The system as recited in claim 12, wherein the microcontroller is further programmed to estimate a number of splicing connections of the charge adaptor based on feedback from a current sensor of the charge adaptor.

14. The system as recited in claim 13, wherein the number of splicing connections is estimated based on a resistance delta measurement that is derived from a look-up table.

15. The system as recited in claim 12, wherein the microcontroller is a local interconnect network (LIN) microcontroller.

16. The system as recited in claim 12, wherein the microcontroller is further programmed to execute the arbitration logic using a sequential energy transfer strategy, a parallel energy transfer strategy, or a staged energy transfer strategy.

17. The system as recited in claim 12, wherein the microcontroller is further programmed to prioritize and stagger the flow of the energy to the first vehicle and the second vehicle based on the arbitration logic.

18. The system as recited in claim 11, wherein the charge adaptor includes a first power line, a second power line, a ground line, a control pilot line, and a proximity pilot line.

19. The system as recited in claim 11, wherein the charge adaptor is connected to the charge source by a first charging cable, the charge adaptor includes a coupler that is configured to connect to a charge port assembly of the first vehicle, and further wherein the charge adaptor is connected to the second vehicle by a second charging cable.

20. The system as recited in claim 19, comprising a second charge adaptor connected to a charge port assembly of the second vehicle, and a third charging cable connected to the second charge adaptor and a third vehicle.
